(19) United States
(12) Patent Application Publication
(10) Pub. No.: US 2006/0086319 A1
(43) Pub. Date: Apr. 27, 2006

(54) Processing gas supply mechanism, film forming apparatus and method, and computer storage medium storing program for controlling same

(75) Inventors: Shigeru Kasai, Nirasaki-shi (JP); Norihiko Yamamoto, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/297,394

(22) Filed: Dec. 9, 2005

Related U.S. Application Data
(63) Continuation-in-part of application No. PCT/JP04/08023, filed on Jun. 9, 2004.

(30) Foreign Application Priority Data
Jun. 10, 2003 (JP) 2003-165295

(51) Int. Cl. H01L 21/306; C23F 1/00; C23C 16/00

(52) U.S. Cl. 118/715; 156/345.33; 156/345.34

(57) ABSTRACT

A processing gas supply mechanism installed on a processing chamber of a film forming apparatus for supplying a processing gas containing a metal organic compound onto a substrate to be processed includes a processing gas inlet opening for introducing the processing gas, a diffusion space for diffusing the processing gas introduced from the processing gas inlet opening, a processing gas supply mechanism main body for forming the processing gas diffusion space, and one or more processing gas supply holes for supplying the processing gas from the diffusion space to a processing space on the substrate in the processing chamber. Further, the processing gas supply holes are shaped to have a Peclet number of 0.5 to 2.5 when the processing gas passes therethrough.

This application is a Continuation-In-Part Application of PCT International Application No. PCT/JP04/008023 filed on Jun. 9, 2004, which designated the United States.

### FIELD OF THE INVENTION

The present invention relates to a processing gas introduction mechanism of a film forming apparatus, a film forming apparatus and method using same, and a computer readable storage medium storing a program for controlling the apparatus to execute the film forming process; and, more particularly, to a processing gas introduction mechanism for supplying a metal organic material to a film forming apparatus, a film forming apparatus and method using same and a computer readable storage medium storing a program for controlling the apparatus to execute the film forming process.

### BACKGROUND OF THE INVENTION

One of important techniques in a manufacturing process of recent highly advanced high-integration semiconductor devices is a CVD (chemical vapor deposition) method capable of forming a film on a fine pattern with a good coverage. With the CVD method, it is possible to form a film of a kind that is difficult to be obtained by a PVD method such as sputtering, and the CVD method is considered as an essential technique for the manufacture of future high-performance semiconductor devices.

For example, in a CVD method using a metal organic compound as a source gas, a metal film such as W, Ni, Mo, Ru, Co, Rh, Re can be formed by using a metal carbonyl source such as W(CO)₆, Ni(CO)₄, MO(CO)₆, Ru₃(CO)₁₂, CO₂(CO)₈, Rh₄(CO)₁₂, Re₂ (CO)₁₀, respectively. Moreover, in addition to these metal films, a metal oxide film, a metal nitride film, a metal silicide film, a metal silicon nitride film, and so forth can also be formed with the CVD method using the metal organic compound. Thus, the CVD method using the metal organic compound is a useful technique in the manufacture of semiconductor devices.

However, the above-mentioned metal organic compound materials have low vapor pressures and, thus, it has been difficult to vaporize the metal organic compound materials and supply the vaporized metal organic compound materials to a film forming apparatus while preventing condensation/solidification thereof on the way.

FIG. 1 exemplifies a prior art film forming apparatus 10. As shown in FIG. 1, the film forming apparatus 10 includes a processing chamber 11 which is evacuated via an exhaust port 11C, and a substrate supporting table 11A for supporting a substrate Wf to be processed thereon is installed within the processing chamber 11, wherein the substrate supporting table 11A incorporates a heater 11a therein.

Further, disposed on the processing chamber 11 is a shower head 11B which serves to introduce a processing gas containing a metal organic compound gas into the processing chamber 11. A metal organic compound gas is supplied into the shower head 11B as a processing gas along with a carrier gas such as Ar via a valve 12A and a line 12 from a bubbler 13 containing therein a source material 13A composed of a metal organic compound such as W(CO)₆, for example. The carrier gas composed of, e.g., Ar is supplied into the bubbler 13 via a line 13B, and the bubbler 13 is configured to generate bubbles.

Thus supplied processing gas is directed into the processing chamber 11 from the shower head 11B through gas holes 11D formed in the shower head 11B, as shown by arrows in the drawing, so that a metal film formed by a thermal decomposition is deposited on the surface of the substrate Wf to be processed.

In such a case, in order to vaporize the metal organic compound, which is a source material, and, further, to supply the vaporized metal organic compound into the processing chamber 11 in a stable manner, the bubbler 13, the line 12, the valve 12A, the shower head 11B, and so on are heated by, for example, a heater (not shown).

However, in case of supplying the processing gas by bubbling, the metal organic compound source of a low vapor pressure and the like exhibits a poor vaporization efficiency, so that it becomes difficult to supply a metal organic compound gas at a great flow rate in a stable manner.

Furthermore, with regard to the structure of the shower head for use in the film forming apparatus, the diameter of the gas holes formed in the shower head is designed to be small, in general, in order to supply the processing gas onto the substrate Wf uniformly, thereby resulting in a pressure increase in the shower head. Since the gas holes 11D are formed to have small diameters in the film forming apparatus 10, there occurs a pressure increase inside the shower head 11B, resulting in a reduction in the feed rate of the metal organic compound gas of the low vapor pressure, thereby making it difficult to supply the gas in a stable manner.

Moreover, if the diameter of the gas holes is enlarged in order to increase the feed rate of the metal organic compound gas, there occurs a problem that the feed rate of the gas supplied onto the substrate Wf to be processed becomes unequal (see, for example, Japanese Patent Laid-open Application Nos. H4-211115, S56-91435 and S59-207631).

### SUMMARY OF THE INVENTION

It is, therefore, an object of the present invention to provide a processing gas supply mechanism capable of solving the above problem, a film forming apparatus and method using same and a computer readable storage medium storing a program for controlling the apparatus to execute the film forming process.

It is a specific object of the present invention to provide a processing gas introduction mechanism capable of uniformly supplying a metal organic compound source gas into a processing chamber at a stable flow rate during a film forming process using a metal organic compound gas; and a film forming method and a film forming apparatus using same.

In accordance with a first aspect of the present invention, there is provided a processing gas supply mechanism, installed on a processing chamber of a film forming apparatus, for supplying a processing gas containing a metal organic compound gas onto a substrate to be processed loaded on a substrate supporting table disposed in the processing chamber, including a processing gas inlet opening for introducing the processing gas therethrough; a diffusion space for diffusing the processing gas introduced from the processing gas inlet opening; a processing gas supply mechanism main body for forming the processing gas diffusion space; and one or more processing gas supply holes for supplying the processing gas into a processing space on the substrate to be processed from the diffusion space, wherein the processing gas supply holes are shaped such that a Peclet number becomes 0.5 to 2.5 when the processing gas passes through the processing gas supply holes.

In accordance with a second aspect of the present invention, there is provided a film forming apparatus including a processing chamber; a substrate supporting table, installed in the processing chamber, for supporting a substrate to be processed; an exhaust port for evacuating the processing chamber; and a processing gas supply mechanism, installed on the processing chamber, for supplying a processing gas containing a metal organic compound onto the substrate to be processed, wherein the processing gas supply mechanism has a processing gas inlet opening for introducing the processing gas therethrough; a diffusion space for diffusing the processing gas introduced from the processing gas inlet opening; a processing gas supply mechanism main body for forming the processing gas diffusion space; one or more processing gas supply holes for supplying the processing gas from the diffusion space into a processing space on the substrate to be processed in the processing chamber, wherein the processing gas supply holes are shaped such that a Peclet number becomes 0.5 to 2.5 when the processing gas passes through the processing gas supply holes.

In accordance with a third aspect of the present invention, there is provided a method for forming a film on a substrate to be processed by using a film forming apparatus, the film forming apparatus including a processing chamber; a substrate supporting table installed in the processing chamber, for supporting a substrate to be processed; an exhaust port for evacuating the processing chamber; and a processing gas supply mechanism installed on the processing chamber, for supplying a processing gas containing a metal organic compound onto the substrate to be processed, wherein the processing gas supply mechanism includes a processing gas inlet opening for introducing the processing gas therethrough; a diffusion space for diffusing the processing gas introduced from the processing gas inlet opening; a processing gas supply mechanism main body for forming the processing gas diffusion space; and one or more processing gas supply holes for supplying the processing gas from the diffusion space into a processing space on the substrate to be processed in the processing chamber, the method, including a processing gas supplying process for supplying the processing gas to the processing space, wherein a Peclet number is set to be in a range between 0.5 and 2.5 when the processing gas passes through the processing gas supply holes in the processing gas supplying process.

In accordance with a fourth aspect of the present invention, there is provided a processing apparatus for processing a substrate by using a processing gas, including a gas supply mechanism having a plurality of gas supply holes, wherein the gas supply holes are shaped to have a Peclet number of 0.5 to 2.5 when the processing gas passes therethrough.

The present invention employs a film forming apparatus having a processing gas supply mechanism capable of reducing a pressure loss along a supply path of a processing gas containing a metal organic compound gas in case of performing a film formation on a substrate to be processed by using the metal organic compound gas. As a result, a pressure increase within the supply path of the processing gas can be suppressed, and the metal organic compound gas having a low vapor pressure can be supplied to the substrate to be processed in a stable manner.

### BRIEF DESCRIPTION OF THE DRAWINGS

The above and other objects and features of the present invention will become apparent from the following description of preferred embodiments, given in conjunction with the accompanying drawings, in which:

FIG. 1 is a schematic view of a prior art film forming apparatus;

FIG. 2 shows a vapor pressure curve of a metal organic compound having a low vapor pressure;

FIG. 3 sets forth a schematic view of a processing gas introduction mechanism and a film forming apparatus in accordance with the present invention;

FIG. 4 presents a cross sectional view that shows a detailed structure of the processing gas introduction mechanism in accordance with the present invention;

FIGS. 5A and 5B set forth perspective views of diffusion members in the processing gas introduction mechanism shown in FIG. 4;

FIGS. 6A and 6B are cross sectional views of a shower plate in the processing gas introduction mechanism shown in FIG. 4;

FIG. 7 offers a plan view of the shower plate in the processing gas introduction mechanism shown in FIG. 4;

FIG. 8 is an enlarged view of a gas hole of the shower plate shown in FIG. 7;

FIG. 9 shows a uniformity in feed rates of a processing gas through a plurality of gas holes and a pressure increase in a gas hole when a Peclet number of the gas hole is varied; and

FIG. 10 describes types of metal organic compound materials and films formed by using them.

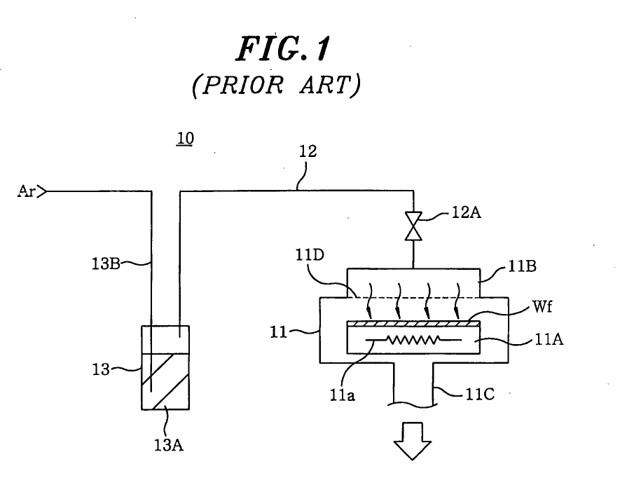

### DETAILED DESCRIPTION OF THE PREFERRED EMBODIMENTS

Outline of the present invention will be first explained.

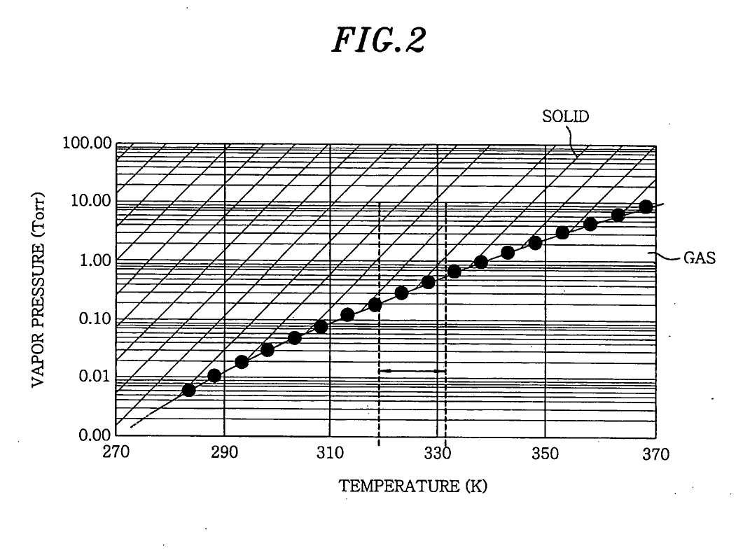

FIG. 2 shows a vapor pressure curve of W(CO)₆ source which is exemplified as a metal organic compound source for use in a film formation employing a CVD method. The vapor pressure of a metal organic compound is not greater than approximately 1 Torr, and the present invention is applied to a case of using a metal organic compound having a vapor pressure not greater than 1 Torr as a processing gas by vaporizing the source.

Referring to FIG. 2, the vapor pressure of W(CO)₆ source is low, i.e., not greater than 0.01 Torr at a room temperature, so it is difficult to vaporize the source to supply it as a processing gas. For the reason, it is common to heat the metal organic compound source and a supply system thereof. For example, they are heated to a temperature of about 310 to 350 K, as shown in FIG. 2. However, the vapor pressure of W(CO)₆ is only about 0.1 to 3 Torr (26.7-399.9 Pa) even in such a case, and it is required to set the internal pressure in a supply path of a metal organic compound gas to be not greater than the vapor pressure of W(CO)₆.

Thus, it is required to form a supply path with a great conductance along which a pressure loss of the metal organic compound gas is reduced and a probability for a pressure increase is low.

The present invention provides a processing gas supply mechanism capable of supplying a metal organic compound gas at a stable flow rate by reducing a pressure loss along a supply path of the vaporized metal organic compound to thereby suppress a pressure increase therein such that the internal pressure in the supply path is maintained less than the vapor pressure of the metal organic compound gas; and, further, provides a film forming method and apparatus using such an inventive processing gas supply mechanism.

### First Preferred Embodiment

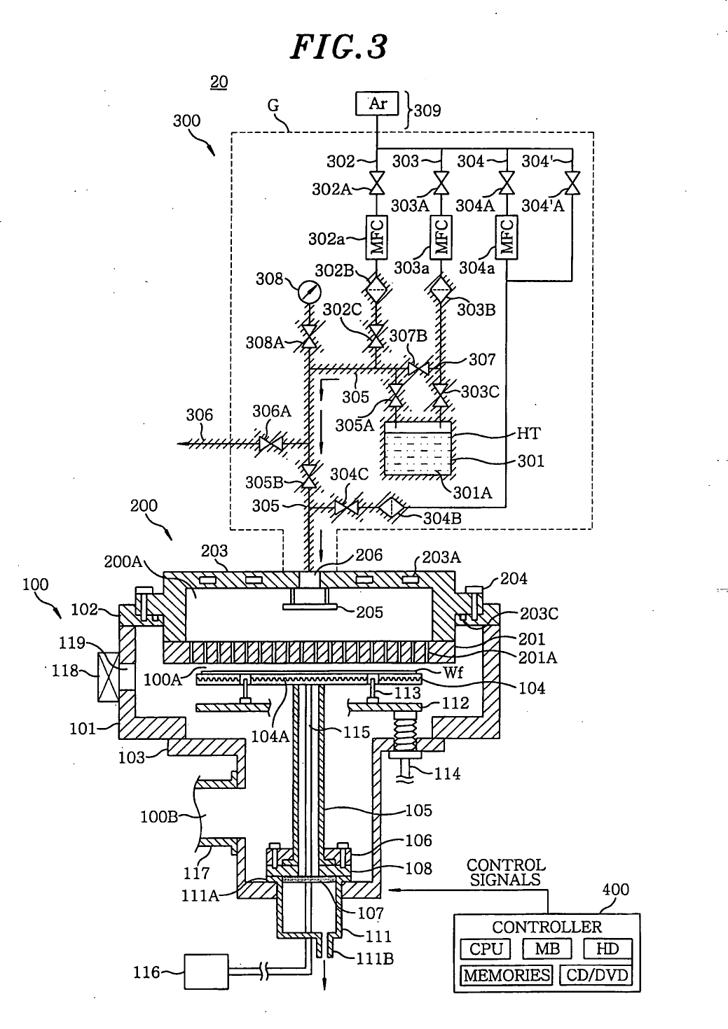

FIG. 3 schematically shows a processing gas supply mechanism in accordance with the present invention and a film forming apparatus 20 including the processing gas supply mechanism.

As shown in FIG. 3, the film forming apparatus 20 includes a processing chamber 100 incorporating a substrate supporting table 104 for supporting a substrate Wf to be processed; a processing gas supply unit 200 installed on the processing chamber 100, for supplying a processing gas containing a metal organic compound onto the substrate Wf to be processed in the processing chamber 100; and a source supply unit 300 for vaporizing a metal organic compound source and supplying it to the processing gas supply unit 200.

First, the processing chamber 100 includes an approximately cylindrical upper chamber 101 and an approximately cylindrical lower chamber 103 attached to an opening formed at a central bottom portion of the upper chamber 101, wherein the lower chamber 103 is smaller than the upper chamber 101. Further, the processing gas supply unit 200 is mounted onto a lid 102 disposed on the upper chamber 101. By attaching or detaching the lid 102 to or from the upper chamber 101, the processing gas supply unit 200 can be attached to or detached from the processing chamber 100.

The substrate supporting table 104 supported by a support portion 105 is installed in the upper chamber 101. The lower member 103 is provided to blanket the opening formed at the central bottom portion of the upper chamber 101, and the support portion 105 is fixed on the bottom of the lower member 103.

Further, the substrate supporting table 104 for supporting the substrate Wf to be processed is formed of a ceramic material such as AlN and Al₂O₃ and a heater 104A is buried therein to heat the substrate Wf to be processed. The support portion 105 is of an approximately cylindrical shape, and a wiring 115 connected to the heater 104A is inserted through the inside of the support portion 105. An electric power is supplied via the wiring 115 to the heater 104A from a power supply 116 connected to the wiring 115.

Moreover, the bottom portion of the support portion 105 is mounted on a mount plate 108 by using a hold ring 106. The surfaces of the support portion 105 and the mount plate 108 facing each other are in surface contact and the hold ring 106 and the mount plate 108 are made of metal, for example, such as Al. Further, the mount plate 108 is airtightly mounted to an opening formed in the bottom portion of the lower chamber 103 via a cover portion 111 with a flange 111A by using a sealing member such as an O-ring.

Further, the cover 111 has a gas exhaust line 111B connected to a gas exhaust unit, and the inside of the support portion 105 is vacuum evacuated via the gas exhaust line 111B. It is also possible to purge the inside of the support portion 105 by way of introducing an inert gas such as Ar or nitrogen into the gas exhaust line 111B, to thereby prevent oxidation of the wiring 115, terminals and the like. He, Kr, Xe or the like can be also used as the inert gas.

An insulation member 107 made up of, for example, ceramic such as Al₂O₃ is disposed in the cover 111 to fasten the wiring 115 while insulating the wiring 115 from the lower chamber 103.

Disposed at a sidewall of the lower chamber 103 is an opening 100B to which a gas exhaust unit, e.g., a pump, is connected via a gas exhaust line 117, whereby the inner space of the film forming apparatus 20 is configured to be evacuated.

Further, the processing gas supply unit 200 includes a flat upper body 203 having an approximately cylindrical shape and an approximately disc-shaped shower plate 201 mounted underneath the upper body 203, and a diffusion space 200A where a processing gas is diffused is formed inside the processing gas supply unit 200.

An approximately annular projection portion is formed at an external wall of the upper body 203. By mounting the projection portion onto the lid 102 and airtightly fastening them via a sealing ring 203C with screws 204, the upper body 203 is fixed on the processing chamber 100. At this time, by configuring the lower surface of the shower plate 201 to face the substrate Wf to be processed in parallel, approximately, a processing space 100A where a processing gas is uniformly supplied onto the substrate Wf to be processed is formed.

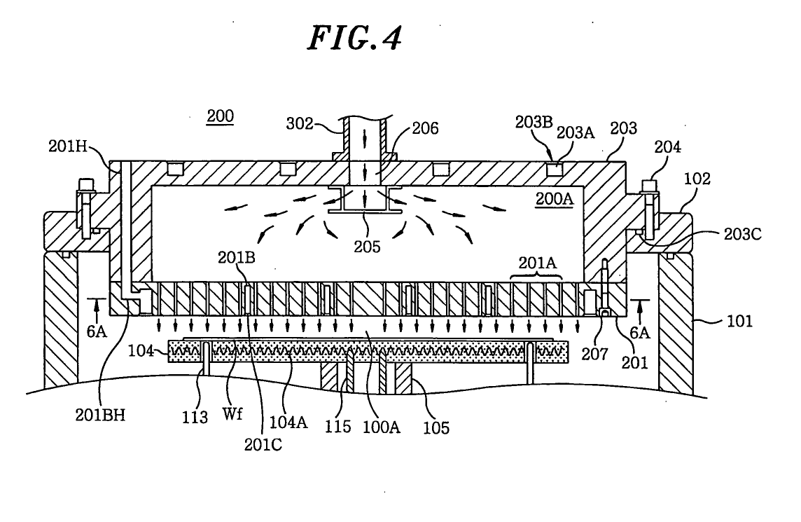

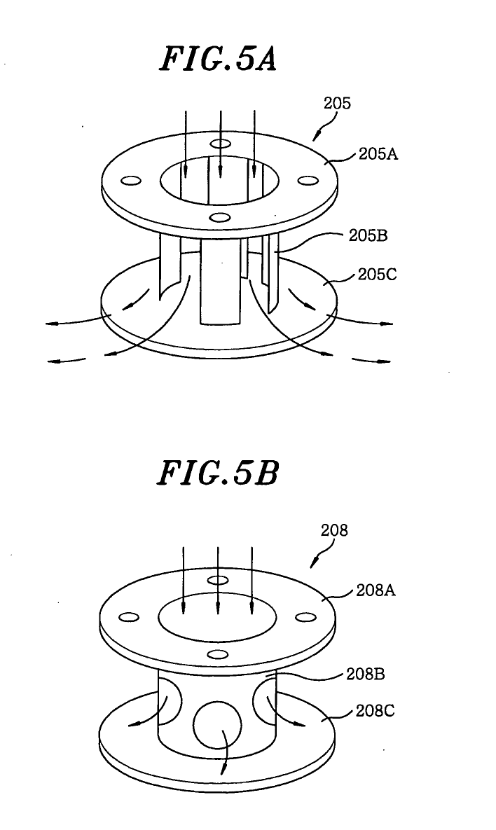

The shower plate 201 is provided with a plurality of gas holes 201A which allow the diffusion space 200A to communicate with the processing space 100A. A processing gas supplied into the diffusion space 200A from a processing gas inlet opening 206 is uniformly introduced into the processing space 100A through the gas holes 201A. At this time, it is also possible to use a diffusion member 205 to be described later with reference to FIGS. 4, 5A and 5B.

In a conventional film forming apparatus, in order to uniformly supply a processing gas into a processing chamber, a gas hole formed in a shower plate is designed to be small, for example, setting the diameter thereof smaller than about 1.0 mm. Therefore, a pressure loss along a gas supplying path is enlarged and the pressure of a processing gas is increased, making it difficult to vaporize a metal organic compound of a low vapor pressure. In accordance with the present invention, however, the diameters of the gas holes 201A are enlarged and optimized to reduce the pressure loss along the gas supplying path for supplying the metal organic compound of the low vapor pressure, whereby it becomes possible to supply a metal organic compound gas onto the substrate Wf to be processed stably and uniformly. Detailed description of the configuration of the shower plate 201 and the gas holes 201A will be described later.

Further, the processing gas supply unit 200 includes a heating mechanism 203B in order that the metal organic compound supplied into the diffusion space 200A maintains a high vapor pressure while preventing resolidification thereof. The heating mechanism 203B is installed at an upper portion of the upper body 203, and a channel 203A is provided in the upper body 203. By supplying a heated heat exchange medium into the channel 203A from a heat medium introduction unit (not shown), the upper body 203 is maintained at a temperature ranging from a room temperature to about 150° C., preferably from about 20 to 100° C. and, more preferably, from about 30 to 50° C.

Moreover, the shower plate 201 is also provided with a channel (not shown) for allowing a heat exchange medium to flow therethrough, so that the shower plate 201 is maintained at a temperature ranging from, for example, 30 to 50° C., and the diffusion space 200A is also maintained at 30 to 50° C.

The processing gas supply unit 200 is connected to a source supply unit 300 for vaporizing a metal organic compound to supply it as a processing gas. The source supply unit 300 (a gas box G) is disposed to include therein a source container 301 for accommodating a solid source 301A composed of a metal organic compound, and the solid source 301A which is vaporized (sublimated) in the source container 301 is transferred to the processing gas inlet opening 206 via a gas line 305 along with a carrier gas supplied into the source container 301 via a gas line 303 to thereby serve as a processing gas.

The carrier gas is an inert gas, e.g., Ar, and a gas source 309 for supplying the inert gas such as Ar is connected to the gas line 303.

Installed on the gas line 303 are valves 303A and 303C, a mass flow controller 303a and a filter 303B.

By opening the valves 303A and 303C, the carrier gas composed of Ar is introduced into the source container 301 while its flow rate is being controlled by the mass flow controller 303a. By controlling the flow rate of the carrier gas, the concentration of the metal organic compound in gas phase sources supplied into the processing chamber can be controlled.

By opening valves 305A and 305B, the carrier gas introduced into the source container 301 is supplied into the processing gas supply unit 200 together with the vaporized solid source 301A as a processing gas from the processing gas inlet opening 206 through the gas line 305. Further, the gas lines 305 and 303 are connected to a gas line 307 on which a valve 307B is installed, and by opening the valve 307B, the inside of the gas line 305 can be purged. Moreover, a pressure gauge 308 is disposed on the gas line 305, and, by opening a valve 308A, the pressure of the gas line 305 can be measured, so that the vaporized state of the source gas can be controlled optimally.

In addition, a gas line 306 with a valve 306A is connected to the gas line 305 and the gas line 306 is in turn connected to a gas exhaust unit such as a gas pump, whereby the exhaustion of the processing gas can be performed.

For example, in case of supplying a processing gas into the diffusion space 200A, the flow rate of the processing gas flowing through the mass flow controller is instable right after the supply of the processing gas is initiated. Thus, by opening the valve 306A prior to opening the valve 305B, the processing gas whose feed rate is instable is exhausted, and, by opening the valve 305B after or while concurrently closing the valve 306 after the flow rate of the processing gas is stabilized, a processing gas with a stable flow rate can be supplied into the diffusion space 200A.

Further, a gas line 304 connected to the gas source 309 is jointed to the gas line 305. Installed on the gas line 304 are valves 304A and 304C, a filter 304B and a mass flow controller 304a. By opening the valves 304A and 304C, it becomes possible to purge the gas line 305 and/or the processing gas supply unit 200 by using the inert gas such as Ar while controlling the flow rate thereof by means of the mass flow controller.

Furthermore, a gas line 304′ is connected to the gas line 304 via a valve 304′A in order to purge the gas line and/or the processing gas supply unit 200 by the inert gas without passing through the mass flow controller 304a and prevent deposits in the gas line 305 and the processing gas supply unit 200.

Likewise, a gas line 302 jointed to the gas source 309 is connected to the gas line 305. Installed on the gas line 302 are valves 302A and 302C, a filter 302B and a mass flow controller 302a. By opening the valves 302A and 302C, the gas line 305 and/or the processing gas supply unit 200 can be purged by the inert gas such as Ar while adjusting the flow rate thereof by means of the mass flow controller 302a.

Furthermore, since the vapor pressure of a metal organic compound is low at a room temperature, a heater HT is installed in a region marked by oblique lines within the gas box G. For example, the source container 301, the gas lines 305, 306 and 307, the gas lines 302, 303 and 304 are heated by the heater HT up to, for example, about 30 to 50° C., so that the vapor pressure of the metal organic compound is maintained high, and the vaporization (sublimation) thereof is eased.

When supplying the processing gas containing the metal organic compound gas is supplied into the processing chamber, it is preferable to install the gas source supply unit 300 as close to the processing gas supply unit 200 as possible in order to reduce a pressure increase within the gas line. For example, it is preferable to shorten the line 305 for connecting the processing gas supply unit 200 and the gas source supply unit 300 disposed thereabove and to increase the conductance of the gas supply line of the processing gas, to thereby suppress a pressure increase of the processing gas within the supply line. For instance, the length of the gas line between the processing gas inlet opening 206 and the source container 301 is preferably not greater than 1500 mm and, more preferably, not greater than 1100 mm when an apparatus space is considered.

Further, the gas line 305 is formed to have an inner diameter of, for example, preferably in a range from about 15 to 100 mm and, more preferably, from 16 to 40 mm, which is greater than that of a conventional gas line, such as ¼″, 2/2″ and ¾″. By reducing a pressure loss by way of increasing the diameter of the gas line, a pressure increase of the processing gas is suppressed while it is being supplied, so that a stable supply of the processing gas containing the metal organic compound of the low vapor pressure can be realized at a great flow rate. Furthermore, when the inner diameter of a valve or a line is increased, it is preferable to have its configuration such that the generation of particles can be prevented.

The film forming apparatus 20 further includes a controller 400. The controller 400 preferably controls processes carried out by the apparatus 20 in a completely automated manner by way of controlling, e.g., flow rates of the heat exchange mediums in the upper body 203 and the shower plate 201 and operations of electrical and mechanical components, e.g., an elevation mechanism 114; the power supply 116 for supplying a power to the heater 104A; a gate valve 118; the gas exhaust units for exhausting gases via the gas exhaust lines 111B, 117 and the gas line 306; and/or the valves 302A, 302C, 303A, 303C, 304A, 304C, 304′A, 305A, 305B, 306A, 307B, 308A. The controller 400 can be implemented by a general purpose computer, e.g., PC (personal computer), which has, e.g., a CPU, a mother board (MB), a hard disk (HD), memories such as ROM and RAM, a CD/DVD drive and so on. In such a case, the process control can be carried out in a completely automated manner under the control of a control program or a software running on the controller 400. Though not specifically depicted in FIG. 3, control signals are provided from the controller 400 to the aforementioned electrical and mechanical components via controller lines (not shown). It should be apparent to those skilled in the art that the control of the electrical and mechanical components can be executed through the use of actuators equipped in those components. Further, though not shown in FIG. 3, the film forming apparatus 20 can be equipped with various sensors needed to monitor process parameters, such as a temperature of the substrate supporting table 104 and a chamber pressure, for the control thereof and monitored signals from the sensors can be fed to the controller 400. The control program can be directly programmed on the controller 400 or can be programmed outside and provided thereto via, e.g., a network or the CD/DVD drive and then stored in, e.g., the hard disk for the execution thereof. The control program may also reside in any storage medium, e.g., a CD or DVD disc, for the execution thereof.

Next, detail of the processing gas supply unit 200 will be described with reference to FIG. 4.

FIG. 4 is an enlarged view of the processing gas supply unit 200 of the film forming apparatus 20 shown in FIG. 3. Here, parts that are already described above will be assigned same reference numerals, and description thereof will be omitted.

Referring to FIG. 4, the processing gas supply unit 200 has the shower plate 201 and the upper body 203 that are attached to each other via screws 207, while forming the diffusion space 200A in which a processing gas is diffused. Further, it is also preferred that the shower plate and the upper body are formed monolithically. A processing gas containing, a gas of a metal organic compound, e.g., W(CO)₆ and the like supplied from the source supply unit 300 is introduced into the diffusion space 200A through the processing gas inlet opening 206 and is supplied into the processing space 100A through the gas holes 201A after being diffused in the diffusion space 200A. At this time, since the diameters of the gas holes 201A are large as described above, a pressure loss in the gas holes 201A, that is, a pressure increase therein, is suppressed, while making it possible to supply the metal organic compound gas of the low vapor pressure in a stable manner.

However, if the diameters of the gas holes 201A are enlarged, flow rates of the supplied processing gas become unequal in the plurality of gas holes 201A, resulting in a deterioration of uniformity of a film formed on a substrate to be processed. Specifically, since the pressure difference between the diffusion space 200A and the processing space 100A becomes small, the processing gas cannot be diffused in the diffusion space 200A sufficiently, and, for example, the tendency that the flow rate of the processing gas discharged from the gas supply holes 201A formed around the shower plate 201 center facing the processing gas inlet opening 206 is great while the flow rate of the processing gas discharged through the gas supply holes 201A formed at a peripheral portion of the shower plate 201 is small is further augmented.

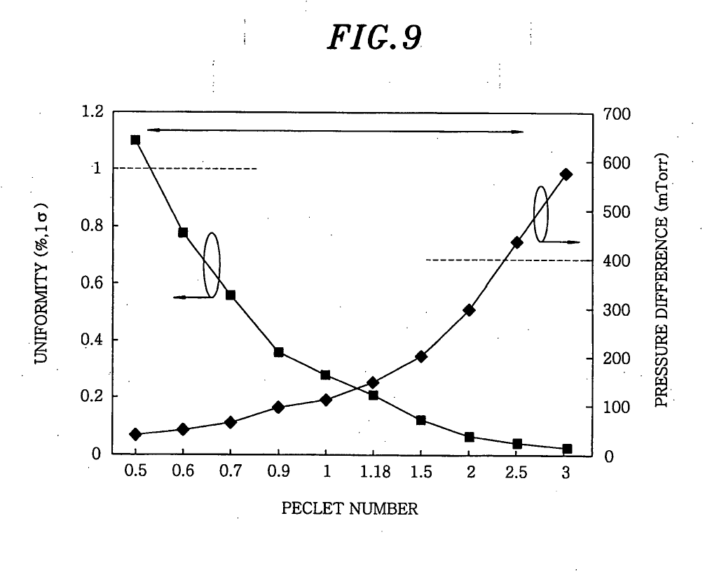

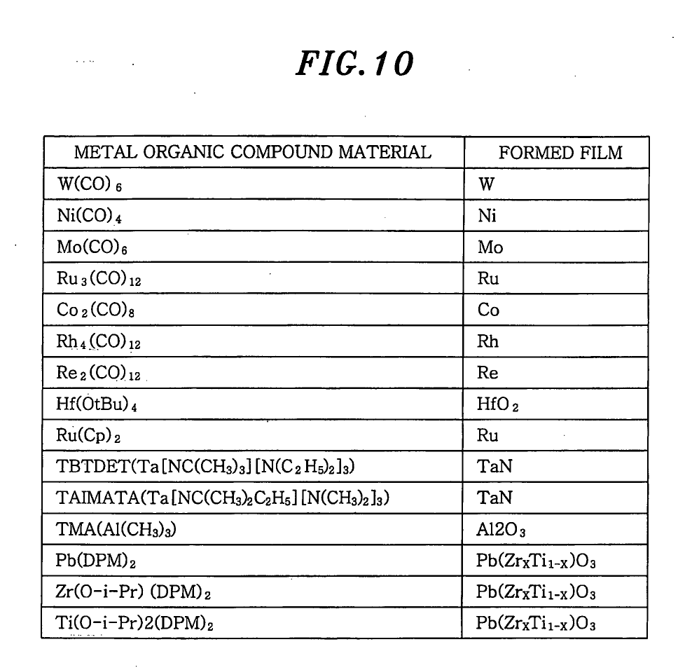

Thus, it is required to optimize the diameters of the gas holes 201A in order to maintain uniformity in feed rates of the processing gas supplied from the plurality of gas holes 201A, while suppressing a pressure increase of the processing gas. The specific method therefor will be described later with reference to FIGS. 8 and 9.

Further, the plurality of gas holes 201A is formed on a multiplicity of concentric circles around the shower plate 201 center corresponding to the center of the substrate Wf to be processed. Further, the gas holes 201A are formed not only in a region corresponding to the substrate Wf to be processed but also in a region extended beyond that. Therefore, a metal film formed on the peripheral portion of the substrate Wf to be processed becomes to have the same thickness as that formed on the central portion thereof, thereby obtaining an in-surface uniformity of film thickness of the metal film formed on the substrate Wf to be processed.

Moreover, in order to diffuse the processing gas supplied as described above into the diffusion space 200A equally, it is also preferable to install a gas diffusion member 205 near the processing gas inlet opening 206 in order to change the flow direction of the supplied processing gas, to thereby allow the processing gas to be diffused in the diffusion space 200A sufficiently such that it reaches the peripheral portion of the shower plate 201.

FIGS. 5A and 5B are perspective views showing exemplary shapes of the diffusion member. First, with regard to the diffusion member 205 shown in FIG. 5A, the diffusion member 205 is formed of a doughnut-shaped upper flange 205A which is attached to a bottom surface of the upper body 203, a disc-shaped lower plate 205C and an approximately cylindrical gas passage 205B inserted between the upper flange 205A and the lower plate 205C, wherein the gas passage 205B is provided with substantially rectangular openings at the sidewall thereof.

The processing gas supplied from an opening of the upper flange 205A is introduced into the diffusion space 200A through, for example, slit-shaped openings of the gas passage 205B while its flow direction is changed by the lower plate 205C. Thus, the relative fraction of the processing gas that reaches the peripheral portion of the shower plate 201 is increased, thereby improving the uniformity in flow rates of the processing gas supplied from the processing gas supply unit 200 in the plurality of gas holes 201A.

Further, FIG. 5B shows a modification of FIG. 5A. A diffusion member 208 includes a doughnut-shaped upper flange 208A which is attached to a bottom surface of the upper body 203, a disc-shaped lower plate 208C and an approximately cylindrical gas passage 208B inserted between the upper flange 208A and the lower plate 208C, wherein the gas passage 208B is provided with substantially circular openings on the sidewall thereof. With the gas passage 208B having the circular openings on the sidewall thereof shown in FIG. 5B, the relative fraction of the processing gas that reaches the peripheral portion of the shower plate 201 can also be increased, and desirable uniformity in feed rates of the processing gas supplied from the processing gas supply unit 200 can also be obtained in the plurality of gas holes 201A.

Furthermore, as will be described hereinbelow, channels are formed in the upper body 203 and the shower plate 201, and, by allowing a heat exchange medium to flow through the channels, the entire processing gas supply unit 200 can be maintained at, for example, about 30 to 50° C., allowing the vaporized metal organic compound to be supplied stably.

With regard to the upper body 203, a channel 203A is formed at the upper surface of the upper body 203, and a heat exchange medium flows therethrough. The channel 203A is formed through steps of forming a groove, which is to be used as the channel 203A, from the exterior surface of the upper body 203; covering the groove with a channel lid 203B; and closing the channel lid 203B to the upper body 203 by, for example, a beam welding.

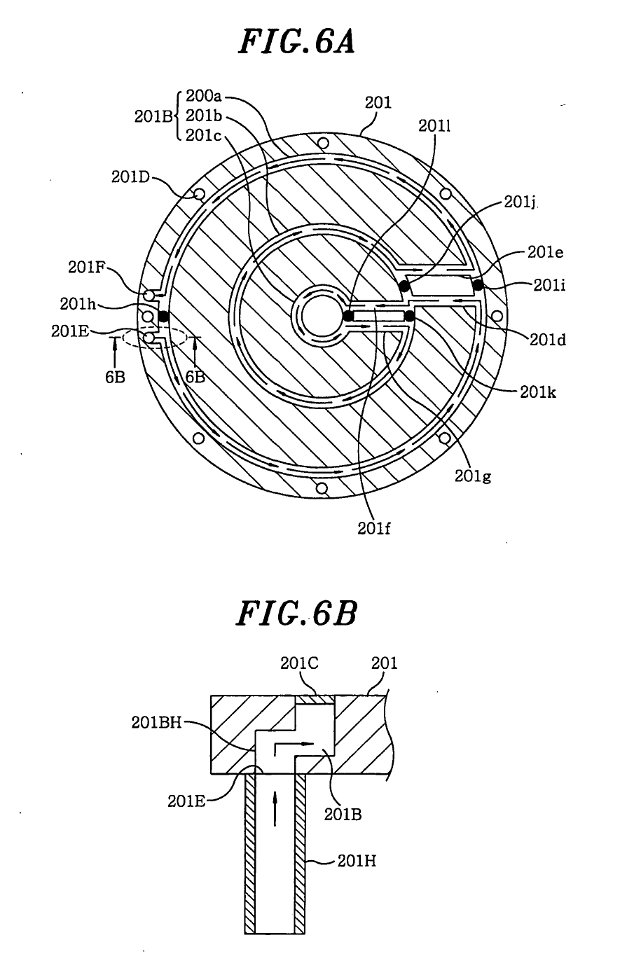

Next, with regard to the shower plate 201, a channel 201B is formed within the shower plate 201 such that it is arranged between the gas supply holes 201A, and a heat exchange medium flows through the channel 201B. The channel 201B is formed through steps of forming a groove, which is to be used as the channel 201B, from the exterior surface of the shower plate 201; covering the groove with a channel lid 201C; and closing the channel lid 201C to the shower plate 201 by, for example, a beam welding. Further, a tube-shaped heat exchange medium inlet part 201H installed at the upper body 203 is connected to the channel 201B via a channel 201BH. Detail of this configuration and the structure of the channel 201B will be described hereinafter in conjunction with FIGS. 6A and 6B.

FIG. 6A is a cross sectional view of the shower plate 201 taken by a line 6A-6A in FIG. 4. Here, the gas holes 201A are not shown.

It is preferable that the channel 201B is formed of two or more sub-channels. In the example shown in FIG. 6A, the channel 201B is formed to have three annular channels in the substantially disc-shaped shower plate 201. Specifically, the channel 201B has a channel 201a formed at the peripheral portion of the shower plate 201, a channel 201b formed inside the channel 201a and a channel 201c formed inside the channel 201b.

Further, the channels 201a and 201b are connected to each other via channels 201d and 201e while the channels 201b and 201c are coupled to each other via channels 201f and 201g.

Furthermore, a stop pin 201i for changing the flow of the heat exchange medium is installed between joints where the channel 201a meets the channels 201d and 201e, respectively. Also, a stop pin 201h is inserted between joints where the channel 201a is connected to a heat exchange medium inlet opening 201E and a heat exchange medium outlet opening 201F, respectively.

Likewise, a stop pin 201j is inserted between joints where the channel 201b is coupled to the channels 201d and 201e, respectively, and a stop pin 201k is installed between joints where the channel 201b meets the channels 201f and 201g, respectively. Furthermore, a stop pin 2011 is installed between joints where the channel 201c is coupled to the channels 201f and 201g, respectively.

The heat exchange medium is introduced into the channel 201a from the heat exchange medium inlet opening 201E, and is forced to flow through the channel 201a counterclockwise due to the presence of the stop pin 201h. When the heat exchange medium flows through about a half round of the channel 201a, the heat exchange medium is then introduced into the channel 201d due to the presence of the stop pin 201i.

Since there are installed the stop pins 201j and 201k in the channel 201b at both sides of the joint where the channel 201d meets the channel 201b, the heat exchange medium is directly introduced into the channel 201f from the channel 201d by crossing the channel 201b. Then, the heat exchange medium is introduced into the channel 201c from the channel 201f and, due to the presence of the stop pin 2011, it is forced to flow through an approximately full round of the channel 201c counterclockwise and, then, is directed into the channel 201b through the channel 201g.

Then, after flowing through an approximately full round of the channel 201b clockwise, the heat exchange medium is introduced again into the channel 201a via the channel 201e. The heat exchange medium sent into the channel 201a flows through an about half round of the channel 201a counterclockwise and then is exhausted through the heat exchange medium outlet opening 201F. Further, distances between the channels 201a, 201b and 201c are designed to have optimum values in order to heat the shower plate 201 uniformly, thereby making it possible to heat the shower plate 201 uniformly by means of the heat exchange medium. In addition, the channels 201a to 201g are formed between the gas supply holes 201A.

Screw holes 201D are holes through which the screws 207 are inserted.

FIG. 6B shows an enlarged view of a cross section taken by a line 6B-6B in FIG. 6A. The tube-shaped heat exchange medium inlet part 201H is welded to the heat exchange medium inlet opening 201E. The heat exchange medium inlet part 201H is inserted through a hole formed in the upper body 203 and is connected to a circulation unit for circulating the heat exchange medium via a distribution pipe distribution pipe, etc. Likewise, a tube-shaped part is coupled to the heat exchange medium output opening 201F to be connected to the circulation unit for circulating the heat exchange medium via a distribution pipe, etc.

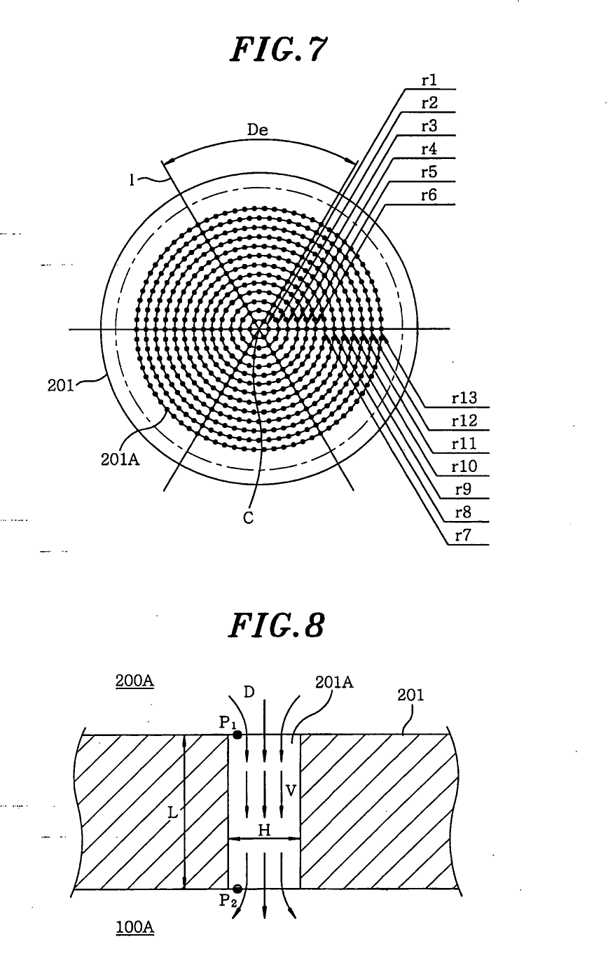

Next, the gas holes 201A of the shower plate 201 will be described in further detail with reference to FIG. 7.

FIG. 7 is a plan view of the shower plate 201. Here, elements other than the gas holes 201A are not shown.

In FIG. 7, the center C of the disc-shaped shower plate is to be located at a position facing almost the center of the substrate Wf to be processed when the processing gas supply unit 200 is mounted on the processing chamber 100.

The plurality of gas holes 201A are formed on concentric circles r1-r13 disposed around the center C. Further, the gas holes 201A are formed on each of the circles r1-r13 such that distances between neighboring gas holes are same. For example, on the circle with a radius of r1, six gas holes 201A are formed with a same distance maintained therebetween. Examples of radii of the circles r1-r13 and the number of gas holes 201A formed thereon are shown as follows.

TABLE 1

| Circle | Radius (mm) | Number of Gas Holes |
|---|---|---|
| r1 | 13.8 | 6 |
| r2 | 27.6 | 12 |
| r3 | 41.4 | 18 |
| r4 | 55.2 | 24 |
| r5 | 69 | 30 |
| r6 | 82.8 | 36 |
| r7 | 96.6 | 42 |
| r8 | 110.4 | 48 |
| r9 | 124.2 | 54 |
| r10 | 138 | 60 |
| r11 | 151.8 | 66 |
| r12 | 165.6 | 72 |
| r13 | 179.4 | 78 |

Further, the gas holes 201A can be formed on the shower plate 201 uniformly by the following method, for example. Three straight lines 1, each crossing the center C, are considered, and an angle De formed between adjacent straight lines 1 is set to be 60 degree.

Then, the gas holes 201A to be arranged on the circles r1-r13 are formed on the straight lines 1.

By arranging the gas holes 201A uniformly with respect to the substrate to be processed, the feed rate of the processing gas supplied onto the substrate to be processed becomes uniform across the entire surface thereof, thereby obtaining a desirable in-surface uniformity of a film formed thereon. The arrangement of the gas holes 201A can be appropriately executed in various ways such that the gas can be uniformly injected toward the substrate to be processed. For instance, the gas holes 201A can be arranged concentrically, radially, or in a zigzag shape.

Optimization of the shape of the gas holes 201A will now be described with reference to FIGS. 8 and 9.

FIG. 8 is a cross sectional view of one of the gas holes 201A of the shower plate 201. In the drawing, the parts that are described above will be assigned like reference numerals, and description thereof will be omitted.

Referring to FIG. 8, the processing gas in the diffusion space 200A is supplied into the processing space 100A through the gas hole 201A. Assume that the thickness of the shower plate, i.e., the length of the gas hole 201A, is L, the flow velocity of the processing gas passing through the gas hole 201A is V, and a diffusion coefficient of the processing gas is D. A Peclet number Pe, which is defined as a ratio of a transport velocity due to flow of the processing gas to a transport velocity due to diffusion of the processing gas, is expressed as follows (Velocity Theory, Hirashi Komiyama, Asakura Bookstore, p. 66).
Pe=V·L/D=(a transport velocity due to flow)/(a transport velocity due to diffusion) [Eq. 1]

For example, if the diameter H of the gas hole 201A is increased, the flow velocity V of the processing gas becomes smaller, so that the Peclet number Pe is also reduced. In such a case, the influence of diffusion of the processing gas upon the transport of processing gas molecules is increased. On the other hand, if the diameter H of the gas hole 201A is reduced, the flow velocity V of the processing gas is increased, so that the Peclet number Pe is also increased. In such a case, the influence of flow of the processing gas upon the transport of the processing gas molecules gets increased. As described, the optimum value of the diameter H of the gas hole 201A can be expressed in terms of an optimum value of the Peclet number of the gas hole based on the processing gas.

With regard to the shower plate 201, if the Peclet number is set to be small, that is, if the diameter H of the gas hole 201A is set to be large, a pressure loss in the gas hole 201A is reduced, so that a difference dP between a pressure P1 at a point where the gas hole 201A contacts the diffusion space 200A and a pressure P2 at a point where the gas hole 201A contacts the processing space 100A is reduced. For the reason, a pressure increase is suppressed while supplying the processing gas, making it possible to supply a metal organic compound gas having a low vapor pressure to the substrate to be processed in a stable manner.

However, as described above, if the Peclet number is set to be small, that is, if the diameter H of the gas hole 201A is set to be large, the flow rates of the processing gas, which is supplied through the plurality of gas holes 201A formed at the shower plate 201, become unequal, resulting in deterioration in uniformity of the film formed on the substrate to be processed. For example, there is a tendency that the flow rates of the processing gas supplied through the gas holes 201A formed near the center of the shower plate 201 facing the processing gas inlet opening 206 are increased while the flow rates of the processing gas supplied through the gas holes 201A formed at the peripheral portion of the shower plate 201 are reduced.

Therefore, it is required to optimize the diameter H of the gas holes 201A, i.e., the Peclet number Pe, in order to regulate the flow rates of the processing gas supplied through the plurality of gas holes 201A uniformly while suppressing a pressure increase of the processing gas by way of reducing a pressure loss in the gas holes 201A.

FIG. 9 provides a result of calculating a value of a pressure loss within the gas hole 201A, i.e., the difference dP between the pressure P1 and the pressure P2, and a variance σ of gas feed rates representing a uniformity in feed rates of gas through the plurality of gas holes 201A when the Peclet number Pe of the gas hole 201A is varied. Here, the gas holes 201A are formed as shown in FIG. 7 and, for example, the calculation was made by assuming the length L of the gas hole 201A and the flow rate of the processing gas as 31.8 mm and 480 sccm, respectively. Further, the gas diffusion members 205 and 208 shown in FIGS. 5A and 5B are not used.

Referring to FIG. 9, the variance of gas feed rates is reduced as the Peclet number increases, and it is preferable to set the Peclet number not smaller than 0.5 in order to obtain a desirable variance not greater than 1%.

Furthermore, in case a metal organic compound used as a source material is W(CO)₆, its vapor pressure is about 320 mTorr (42.7 Pa) at 50° C. and about 740 mTorr (98.7 Pa) at 60° C., as shown in FIG. 2. Therefore, the pressure within the gas hole 201A needs to be maintained not greater than the vapor pressure of W(CO)₆ and the difference dP between the pressures P1 and P2 needs to be maintained not greater than 400 mTorr by considering a pressure loss in a gas line or the shower head other than the gas hole 201A. For this, the Peclet number is preferably set to be not greater than 2.5.

Thus, in case of supplying a processing gas containing a metal organic compound gas, the Peclet number of the gas hole 201A is preferably set to range from 0.5 to 2.5 and the diameter H of the gas hole is preferably set to range from 1.5 to 6 mm. More preferably, the Peclet number and the diameter H of the gas hole are set to range from 1 to 2.5 and from 1.5 to 4.6 mm, respectively.

Further, it is preferable to vary the length L of the gas hole or the thickness of the shower plate appropriately in order to optimize the Peclet number. For example, in order to reduce the Peclet number, the length L is set to be small, preferably not greater than 50 mm and more preferably not greater than 35 mm. Furthermore, given that a channel for a heat exchange medium is formed in the shower plate 201, it is preferably to set the length L to be not smaller than 10 mm.

In addition, by installing a part for changing the flow of the processing gas, e.g., the diffusion member 205 or 208, in the diffusion space 200A, the uniformity in the flow rates of the supplied processing gas through the plurality of gas holes 201A can be improved. Accordingly, the range for the preferred Peclet number can be expanded with regard to the gas hole 201A, and, for example, it becomes possible to use the Peclet number not greater than 0.5 in this embodiment.

In case of performing a film forming process on a substrate to be processed in the above-described film forming apparatus 20, a gate valve 118 is opened and the substrate to be processed is transferred through a loading/unloading port 119 onto the substrate supporting table 104 by, e.g., a transfer arm (not shown). Then, an approximately disc-shaped pin attachment plate 112 provided with a plurality of lift pins 113 is elevated by an elevation mechanism 114 to transfer the substrate to be processed with the lift pins 113, to thereby load the substrate to be processed on the substrate supporting table 104.

Thereafter, in order to perform a film formation on the substrate Wf to be processed, a carrier gas such as Ar is supplied into the source container 301 via the gas line 303 while its flow rate is controlled by the mass flow controller 303a.

Then, a processing gas containing a vaporized metal organic compound, e.g., W(CO)₆, and the carrier gas is introduced into the diffusion space 200A from the processing gas inlet opening 206 via the gas line 305.

The metal organic compound gas and the carrier gas serving as the processing gas supplied into the diffusion space 200A are then introduced into the processing space 100A through the gas holes 201A. Typically, at this time, the substrate Wf to be processed is heated up to about 300 to 600° C. by the substrate supporting table 104 which is heated up to about 300 to 600° C. by the heater 104A, and a W film (tungsten film) is formed on the substrate to be processed by the thermal decomposition of W(CO)₆. At this time, the flow rate of Ar serving as the carrier gas is set to be 100 to 1000 sccm and the pressure of the processing space is maintained at 1 to 100 Pa.

All of the processes and conditions thereof related with the film forming method carried out in accordance with the present invention can be preferably controlled in a fully automated manner by the control program running on the controller 400. Further, it should be also appreciated that the film forming method of the present invention may also be controlled by more than one controllers or computers as well.

Though the preferred embodiment of the present invention has been described for the case of using W(CO)₆ as a metal organic compound, the method disclosed in the preferred embodiment can also be applied to cases using other types of metal organic compounds. Examples of available metal organic materials and types of films that can be formed thereby are illustrated in FIG. 10.

While the invention has been shown and described with respect to the preferred embodiment, it will be understood by those skilled in the art that various changes and modification may be made without departing from the spirit and scope of the invention as defined in the following claims.

What is claimed is:

1. A processing gas supply mechanism, installed on a processing chamber of a film forming apparatus, for supplying a processing gas containing a metal organic compound gas onto a substrate to be processed loaded on a substrate supporting table disposed in the processing chamber, comprising:
a processing gas inlet opening for introducing the processing gas;
a diffusion space for diffusing the processing gas introduced from the processing gas inlet opening;
a processing gas supply mechanism main body for forming the processing gas diffusion space; and
one or more processing gas supply holes for supplying the processing gas from the diffusion space to a processing space on the substrate to be processed in the processing chamber,
wherein the processing gas supply holes are shaped to have a Peclet number of 0.5 to 2.5 when the processing gas passes therethrough.

2. The processing gas supply mechanism of claim 1, wherein the metal organic compound is W(CO)₆.

3. The processing gas supply mechanism of claim 1, wherein the processing gas contains a carrier gas composed of an inert gas.

4. The processing gas supply mechanism of claim 1, wherein the processing gas supply mechanism main body has a shower plate placed approximately in parallel to the substrate to be processed; and the number of the processing gas supply holes is greater than one, and the processing gas supply holes are formed on the shower plate.

5. The processing gas supply mechanism of claim 1, wherein the diffusion space includes therein a diffusion member for changing a flow direction of the processing gas introduced from the processing gas inlet opening to thereby diffuse the processing gas into the diffusion space.

6. The processing gas supply mechanism of claim 1, wherein the processing gas supply mechanism main body has a heating mechanism.

7. The processing gas supply mechanism of claim 6, wherein the heating mechanism is a flow channel formed in the processing gas supply mechanism main body and has a structure to allow a heated heat exchange medium to flow through the flow channel.

8. A film forming apparatus comprising:
a processing chamber;
a substrate supporting table, disposed in the processing chamber, for supporting a substrate to be processed;
an exhaust port for evacuating the processing chamber; and
a processing gas supply mechanism, disposed on the processing chamber, for supplying a processing gas containing a metal organic compound onto the substrate to be processed,
wherein the processing gas supply mechanism includes:
a processing gas inlet opening for introducing the processing gas;
a diffusion space for diffusing the processing gas introduced from the processing gas inlet opening;
a processing gas supply mechanism main body for forming the diffusion space; and
one or more processing gas supply holes for supplying the processing gas from the diffusion space to a processing space on the substrate to be processed in the processing chamber,
wherein the processing gas supply holes are shaped to have a Peclet number of 0.5 to 2.5 when the processing gas passes therethrough.

9. The film forming apparatus of claim 8, wherein the metal organic compound is selected from the group consisting of W(CO)₆, Ni(CO)₄, Mo(CO)₆, Ru₃(CO)₁₂, CO₂ (CO)₈, Rh₄(CO)₁₂, Re₂(CO)₁₂, Hf(OtBu)₄, Ru(Cp)₂, TBTDET, TAIMATA, TMA, Pb(DRM)₂, Zr(O-i-Pr) (DPM)₂ and Ti (O-i-Pr) 2 (DPM)₂.

10. The film forming apparatus of claim 8, the processing gas contains a carrier gas composed of an inert gas.

11. The film forming apparatus of claim 8, the processing gas supply mechanism main body has a shower plate placed approximately in parallel to the substrate to be processed; and the number of the processing gas supply holes is greater than one, and the processing gas supply holes are formed on the shower plate.

12. The film forming apparatus of claim 8, wherein the diffusion space includes therein a diffusion member for changing a flow direction of the processing gas introduced from the processing gas inlet opening to thereby diffuse the processing gas into the diffusion space.

13. The film forming apparatus of claim 8, wherein the processing gas supply mechanism main body has a heating mechanism.

14. The film forming apparatus of claim 13, wherein the heating mechanism is a flow channel formed in the processing gas supply mechanism main body and has a structure to allow a heated heat exchange medium to flow through the flow channel.

15. The film forming apparatus of claim 8, wherein a source supply unit for generating the processing gas by vaporizing a source material and supplying the processing gas into the processing gas supply mechanism is connected thereto via a connecting pipe, and an inner diameter of the connecting pipe ranges from 15 mm to 100 mm.

16. A method for forming a film on a substrate to be processed by using a film forming apparatus, the film forming apparatus including:
a processing chamber;
a substrate supporting table, disposed in the processing chamber, for supporting a substrate to be processed;
an exhaust port for evacuating the processing chamber; and
a processing gas supply mechanism, disposed on the processing chamber, for supplying a processing gas containing a metal organic compound onto the substrate to be processed,
wherein the processing gas supply mechanism includes:
a processing gas inlet opening for introducing the processing gas;
a diffusion space for diffusing the processing gas introduced from the processing gas inlet opening;
a processing gas supply mechanism main body for forming the diffusion space; and
one or more processing gas supply holes for supplying the processing gas from the diffusion space into a processing space on the substrate to be processed in the processing chamber,
the method, comprising:
a processing gas supplying process for supplying the processing gas to the processing space,
wherein the processing gas supplying process includes a process where a Peclet number is 0.5 and 2.5 when the processing gas passes through the processing gas supply holes.

17. The method of claim 16, wherein the metal organic compound is W(CO)₆.

18. The method of claim 16, the processing gas contains a carrier gas composed of an inert gas.

19. A computer readable storage medium storing therein a program for controlling the film forming method of claim 16.

20. A processing apparatus for processing a substrate by using a processing gas, comprising:
a gas supply mechanism having a plurality of gas supply holes, wherein the gas supply holes are shaped to have a Peclet number of 0.5 to 2.5 when the processing gas passes therethrough.
